(19) United States
(12) Patent Application Publication
(10) Pub. No.: US 2026/0262394 A1
(43) Pub. Date: Sep. 3, 2026

(54) DISPLAY DEVICE

(71) Applicant: LG Display Co., Ltd., Seoul (KR)

(72) Inventors: Changhoon OH, Paju-si (KR); Minuk KANG, Paju-si (KR)

(73) Assignee: LG Display Co., Ltd., Seoul (KR)

(21) Appl. No.: 19/552,626

(22) Filed: Feb. 27, 2026

(30) Foreign Application Priority Data
Feb. 28, 2025 (KR) 10-2025-0027101

(51) Int. Cl. H10K 59/123; H10K 59/122; H10K 59/35

(52) U.S. Cl. CPC H10K 59/123; H10K 59/122; H10K 59/351; H10K 59/352

(57) ABSTRACT

A disclosed display device includes: a substrate including a first pixel having a first light emitting region; at least one transistor on the substrate; a first via layer on the at least one transistor; at least one metal pattern on the first via layer; a second via layer on the at least one metal pattern and comprising at least one projection overlapping the at least one metal pattern, the at least one projection being in the first light emitting region; a pixel-defining layer on the second via layer and configured to define the first light emitting region; and a pixel electrode on the second via layer and the at least one projection.

### CROSS REFERENCE TO RELATED APPLICATION

The present application claims priority to Korean Patent Application No. 10-2025-0027101, filed Feb. 28, 2025, the entire contents of which are incorporated herein for all purposes by this reference.

### FIELD

The present disclosure relates to a display device.

### BACKGROUND

With the progress of the information-oriented society, various types of demands for display devices which display an image are increasing. Further, various types of display devices, such as a liquid crystal display device and an organic light emitting display device, have been used.

The images displayed in the display device may be still images or moving images. If the images are moving images, the images may be various kinds such as sports images, game images, movies, and the like. The display device may include a plurality of pixels and a plurality of switching elements for driving the pixels.

### SUMMARY

An object to be achieved by the present disclosure is to provide a display device capable of controlling a light emission angle(s) of a light-emitting element(s) and improving a viewing angle (of the display device) for the user.

Objects to be achieved by the present disclosure are not limited to the above-mentioned objects, and other objects not mentioned can be inferred from the general description and the description of example embodiments provided below by those skilled in the art to which the present disclosure relates.

To achieve these objects and other advantages of the present disclosure, as embodied and broadly described herein, a display device according to one or more example embodiments includes: a substrate including a first pixel having a first light emitting region; at least one transistor on the substrate; a first via layer on the at least one transistor; at least one metal pattern on the first via layer; a second via layer on the at least one metal pattern and comprising at least one projection overlapping the at least one metal pattern, the at least one projection being in the first light emitting region; a pixel-defining layer on the second via layer and configured to define the first light emitting region; and a pixel electrode on the second via layer and the at least one projection.

In another aspect of the present disclosure, a display device according to one or more example embodiments includes: a plurality of pixels defined on a substrate, including a first pixel having a first light emitting region; a transistor on the substrate; a first via layer on the transistor; at least one metal pattern on the first via layer; a second via layer on the at least one metal pattern and comprising at least one projection overlapping the at least one metal pattern in the first light emitting region, the at least one projection protruding from an upper surface of the second via layer in a direction away from the substrate; a pixel-defining layer on the second via layer and including an opening to define the first light emitting region; and a light emitting element on the second via layer and overlapping the at least one projection and the at least one metal pattern in the first light emitting region.

Other details of various example embodiments are included in the below detailed description and the accompanying drawings.

A display device according to one or more example embodiments of the present disclosure includes a metal pattern disposed on a first via layer and a projection on a second via layer overlapping the metal pattern, thereby being capable of improving a light emission angle(s) of the light emitting element and a viewing angle for the user.

A display device according to one or more example embodiments of the present disclosure can improve light extraction characteristics and efficiency and reduce power consumption by controlling a light emission angle(s) of the light emission elements, thereby improving a viewing angle of the display device for the user.

Effects which may be obtained by the present disclosure are not limited to the aforementioned effects, and other technical effects not described above can be understood from the following description by persons skilled in the art to which the present disclosure pertains.

### BRIEF DESCRIPTION OF THE DRAWINGS

The accompanying drawings, which are included to provide a further understanding of the present disclosure and are incorporated in and constitute a part of this application, illustrate various example embodiments of the present disclosure and together with the description serve to explain various principles of the disclosure.

FIG. 1 is a plan view illustrating a display device according to one or more example embodiments.

FIG. 2 is a cross-sectional view illustrating a display device according to one or more example embodiments in a folded or bent state.

FIG. 3 is a block diagram illustrating a display device according to one or more example embodiments.

FIG. 4 is a cross-sectional view illustrating a display device according to an example embodiment.

FIG. 5 is an enlarged view of region A1 of FIG. 4.

FIG. 6 is a cross-sectional view illustrating a display device according to another example embodiment.

FIG. 7 is an enlarged view of region A2 of FIG. 6.

FIG. 8 is an example of a plan view illustrating a plurality of pixels in a display device according to an example embodiment.

FIG. 9 is an example of a cross-sectional view taken along line I-I′ in FIG. 8.

FIG. 10 is another example of a cross-sectional view taken along line I-I′ in FIG. 8.

FIG. 11 is a cross-sectional view illustrating an example of a metal pattern and a projection in a display device according to an example embodiment.

FIG. 12 is a cross-sectional view illustrating another example of a metal pattern and a projection in a display device according to an example embodiment.

FIG. 13 is another example of a plan view illustrating a plurality of pixels in a display device according to an example embodiment.

FIG. 14 is a plan view illustrating various examples of a projection or protrusion in a display device according to an example embodiment.

### DETAILED DESCRIPTION

Hereinafter, various example embodiments of the present disclosure will be described with reference to the drawings. In this specification, where a component (or, an area, a layer, a part, etc.) is referred to as being “on,” “connected to,” or “combined with” another component, the component may be directly on, connected to, or combined with the other component, or a third component may be present therebetween such that the component is indirectly on, connected to, or combined with the other component.

Like reference numerals refer to like elements unless otherwise specified. Additionally, in the drawings, the thicknesses, proportions, and dimensions of components may be exaggerated for effective description. The term “and/or” includes all of one or more combinations defined by related components.

It should be understood that where terms like “first” and “second” are used herein to describe various components, these components should not be limited by these terms. The above terms are used only to refer to one component separately from another. For example, a first component may be referred to as a second component, and vice versa, without departing from the scope of the present disclosure. Singular expressions and terms used herein also encompass or include plural expressions and terms, and vice versa, unless the context clearly indicates otherwise.

In addition, such terms as “below,” “the lower side,” “on,” and “the upper side” are used to describe a relationship of configurations shown in the drawings. The terms are described as a relative concept based on a direction shown in the drawings. The spatially relative terms should be understood to encompass different directions of elements in use or operation based on their orientation, in addition to the directions shown in the drawings.

In various embodiments of the present disclosure, a term like “include,” “comprise,” “including,” or “comprising,” specifies the presence of a property, a recited number, a step, a process, an element and/or a component, or a combination thereof, but does not exclude presence or addition of other properties, recited numbers, steps, processes, elements and/or components, or a combination thereof.

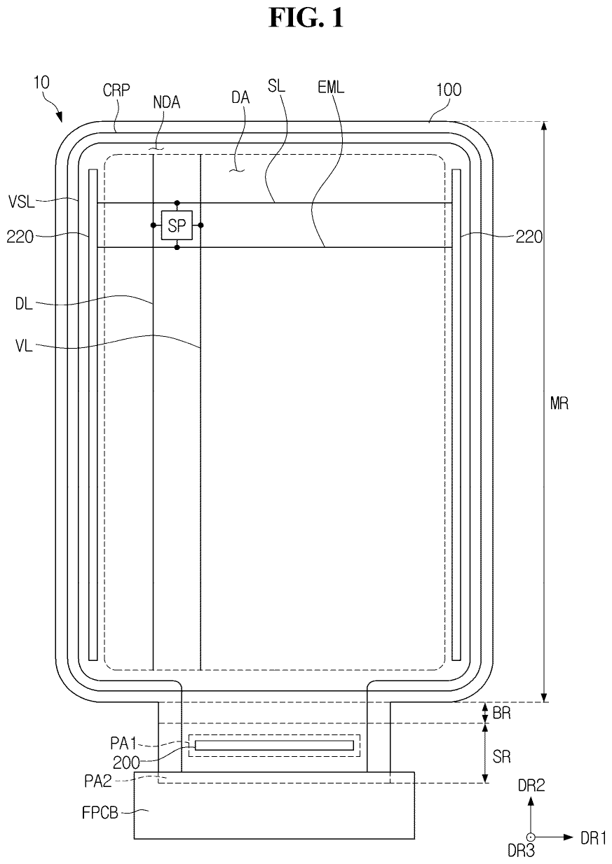

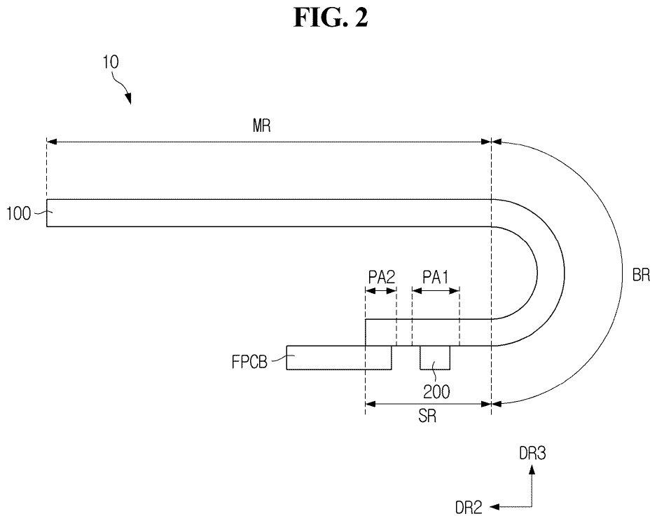

FIG. 1 is a plan view illustrating a display device according to one or more example embodiments, and FIG. 2 is a cross-sectional view illustrating a display device in a folded or bent state according to one or more example embodiments in a folded or bent state.

As shown in FIGS. 1 and 2, the display device 10 may be applied to a portable electronic device, such as a mobile phone, a smart phone, a tablet personal computer, a mobile communication terminal, an electronic organizer, an e-book reader, a portable multimedia player (PMP), a navigation apparatus, an ultra-mobile PC (UMPC), and the like. As another example, the display device 10 may be applied to various wearable devices, such as smart watches, watch phones, glass-like displays, head-mounted displays (HMDs), and the like. As yet another example, the display device 10 may be applied as a display unit of a television, a notebook computer, a monitor, a billboard, an Internet of things (IoT) device, and the like.

The display device 10 may include a display panel 100, a display driver 200, and a scan driver 220. The display panel 100 may include a main region MR, a sub region SR, and a bending region BR between the main region MR and the sub region SR.

The main region MR may include a display region DA and a non-display region NDA. A planar shape of the display region DA may, for example, be a rectangular shape. As another example, the planar shape of the display region DA may be a square shape, a circular shape, an oval shape, or other polygonal shape. For example, the display region DA may have a rectangular shape with one or more rounded or curved edges or corners, but is not limited thereto, and may have a rectangular shape with straight edges and angular corners.

A first direction DR1 and a second direction DR2 may intersect perpendicularly in a plan view, and a third direction DR3 may intersect a plane which includes the first direction DR1 and the second direction DR2. Hereinafter, in an example as illustrated in FIG. 1, the first direction DR1 may correspond to a rightward direction, a direction opposite the first direction DR1 may correspond to a leftward direction, the second direction DR2 may correspond to an upward direction, and a direction opposite the second direction DR2 may correspond to a downward direction, but an arrangement relationship among components is not limited to the directions.

The display region DA may include a plurality of pixels SP configured to display an image. A pixel SP may emit light through a light emitting region or an opening region. The pixel SP may include a pixel circuit including switching elements, a pixel-defining layer configured to define the light emitting region, and a self-light emitting element. For example, the self-light emitting element may include at least one among an organic light emitting diode including an organic light emitting layer, a quantum dot LED including a quantum dot light emitting layer, an inorganic LED including an inorganic semiconductor, and a micro-LED or a nano-LED, but is not limited thereto.

The display region DA may include short sides extending along the first direction DR1 and long sides extending along the second direction DR2. The non-display region NDA may be disposed around the display region DA. The non-display region NDA may include a first side disposed in the first direction DR1 from the display region DA, a second side disposed in an opposite direction to the first direction DR1 from the display region DA, a third side disposed in the second direction DR2 from the display region DA, and a fourth side disposed in an opposite direction to the second direction DR2 from the display region DA. Here, the first side of the non-display region NDA may be a right side, the second side thereof may be a left side, the third side thereof may be an upper side, and the fourth side thereof may be a lower side.

Scan lines SL may extend in the first direction DR1 and may be spaced apart from each other in the second direction DR2. The scan lines SL may supply a scan signal to the plurality of pixels SP sequentially.

Light emitting control lines EML may extend in the first direction DR1 and may be spaced apart from each other in the second direction DR2. The light emitting control lines EML may supply a light emission signal to the plurality of pixels SP sequentially.

Data lines DL may extend in the second direction DR2 and may be spaced apart from each other in the first direction DR1. The data lines DL may supply a data voltage to the pixels SP. The data voltage may determine luminance of each of the pixels SP.

Power supply lines VL may extend in the second direction DR2 and may be spaced apart from each other in the first direction DR1. The power supply lines VL may supply a power supply voltage to the pixels SP. Here, the power supply voltage may include a driving voltage, a low potential voltage, an initialization voltage, a reference voltage, and a bias voltage, but is not limited thereto.

The scan driver 220 may be disposed on each of the first side and the second side of the non-display region NDA. The scan driver 220 may include a plurality of transistors and may supply scan signals to the plurality of pixels SP. The scan signals of the scan driver 220 may select the pixels SP to which the data voltage is supplied, and the selected pixels SP may receive the data voltage through the data lines DL. The scan driver 220 may be disposed in the non-display region NDA in a Gate-In-Panel (GIP) manner.

A low potential line VSL may be disposed in the non-display region NDA and may surround the scan driver 220 and the display region DA. For example, the low potential line VSL may extend from a flexible film FPCB, pass through the sub region SR and the bending region BR, be disposed on the first to fourth sides of the non-display region NDA, and surround the scan driver 220 and the display region DA.

The bending region BR and the sub region SR may extend from a lower side of the main region MR. The bending region BR may be disposed between the sub region SR and the main region MR. As illustrated in FIG. 2, the bending region BR may be bent with respect to a bending axis in the first direction DR1, and the main region MR and the sub region SR may overlap in a thickness direction or the third direction DR3. The display panel 100 may be bent in a manner in which a lower surface of the main region MR and an upper surface of the sub region SR face each other.

The sub region SR may include a first pad region PA1 and a second pad region PA2. The first pad region PA1 may be disposed at a center of the sub region SR and may allow the display driver 200 to be mounted therein. The first pad region PA1 may include a plurality of pad portions and may be electrically connected to the display driver 200. The display driver 200 may supply a data voltage(s) to the data line(s) of the display panel 100. The display driver 200 may be formed as one or more integrated circuits (ICs). For example, the display driver 200 may be disposed in the first pad region PA1 in a Chip-on-Plastic or Chip-on-Glass configuration. As another example, the display driver 200 may be disposed in a Chip-on-Film configuration.

The second pad region PA2 may be disposed at a lower edge of the sub region SR in an unfolded state (see, e.g., FIG. 1) or at a left edge of the sub region SR in a folded state. The second pad region PA2 may include a plurality of pad portions and may be electrically connected to one or more flexible films FPCB. For example, the flexible film(s) FPCB may electrically connect at least one of a timing controller, a power supply unit, and a memory to the display panel 100.

A crack sensing pattern CRP may surround the low potential line VSL, the scan driver 220, and the display region DA. The crack sensing pattern CRP may be disposed on the first to fourth sides of the non-display region NDA, and fully surround the display region DA. As another example, the crack sensing pattern CRP may not be disposed in part of the non-display region NDA. When an external impact is applied to the display device 10, the crack sensing pattern CRP may be damaged, and the damaged crack sensing pattern CRP may show that a crack is generated in the display device 10.

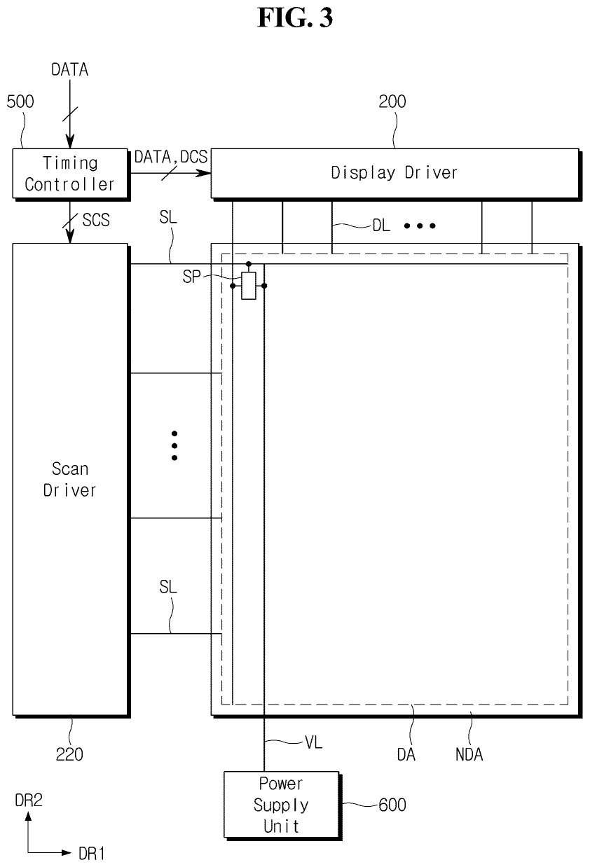

FIG. 3 is a block diagram illustrating a display device according to one or more example embodiments.

According to FIG. 3, the display panel 100 may include the display region DA and the non-display region NDA. The display region DA may include a plurality of pixels SP, the power supply line VL connected to the pixel(s) SP, a scan line SL, and a data line DL.

Each of the plurality of pixels SP may be connected to a corresponding scan line SL, a corresponding data line DL, and the power supply line VL. Each of the plurality of pixels SP may include a transistor, a light emitting element, and a capacitor.

The scan lines SL may extend in the first direction DR1 and may be spaced apart from each other in the second direction DR2 intersecting the first direction DR1. The scan lines SL may supply the scan signal to the plurality of pixels SP sequentially.

The data lines DL may extend in the second direction DR2 and may be spaced apart from each other in the first direction DR1. A data line DL may supply a data voltage to the corresponding pixel(s) SP. The data voltage may determine luminance of the pixel(s) SP.

The power supply lines VL may extend in the second direction DR2 and may be spaced apart from each other in the first direction DR1. The power supply lines VL may supply a power supply voltage to the plurality of pixels SP. The power supply voltage may include a driving voltage, a low potential voltage, an initialization voltage, a reference voltage, and a bias voltage, but is not limited thereto.

The scan driver 220 may include a plurality of transistors and may generate scan signals based on a scan control signal SCS. The scan driver 220 may shift a scan signal using a shift register and may supply the shifted scan signals to the scan lines SL sequentially. The scan signals of the scan driver 220 may select the pixels SP to which the data voltage is supplied, and the selected pixels SP may receive a data voltage through the data lines DL. The scan driver 220 may be disposed on one side or both sides of the non-display region DNA in the Gate-In-Panel (GIP) manner.

The timing controller 500 may receive digital video data DATA and a timing signal from a graphic device or a set module. The timing controller 500 may generate a data control signal DCS based on a timing signal. The timing controller 500 may control an operation timing of the display driver 200 by supplying the digital video data DATA and the data control signal DCS to the display driver 200. The display driver 200 may convert the digital video data DATA into analog data voltages and may supply them to the data lines DL. The timing controller 500 may generate the scan control signal SCS based on the timing signal. The timing controller 500 may control an operation timing of the scan driver 220 by supplying the scan control signal SCS to the scan driver 220. The timing controller 500 may vary a drive frequency of the display panel 100 based on an input frequency received from the graphic device.

The power supply unit 600 may supply a power supply voltage to the power supply line(s) VL. The power supply voltage may include a driving voltage, a low potential voltage, an initialization voltage, a reference voltage, and a bias voltage, but is not limited thereto. The power supply unit 600 may generate a driving voltage and supply it to a driving voltage line, generate an initialization voltage and supply it to an initialization voltage line, generate a bias voltage and supply it to a bias voltage line, generate a reference voltage and supply it to a reference voltage line, and generate a low potential voltage and supply it to the low potential line VSL.

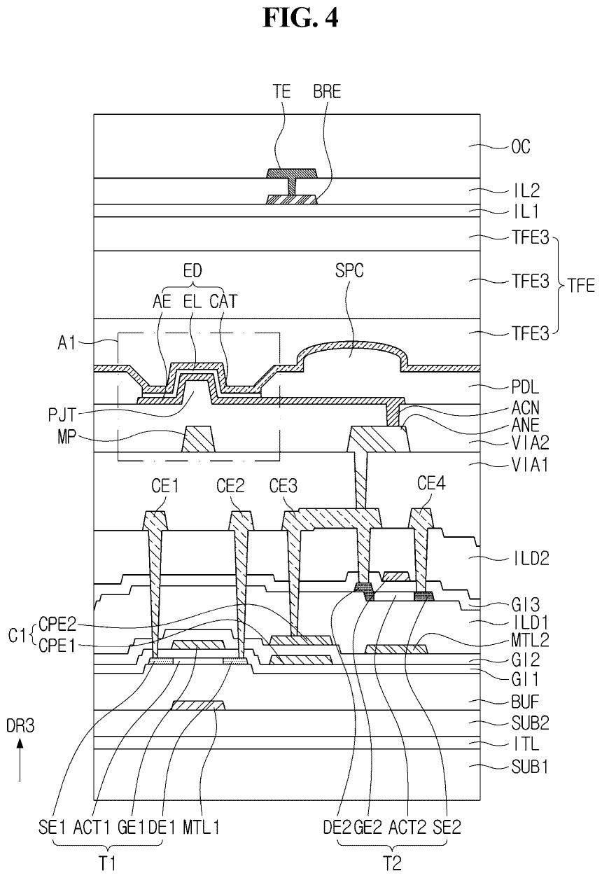

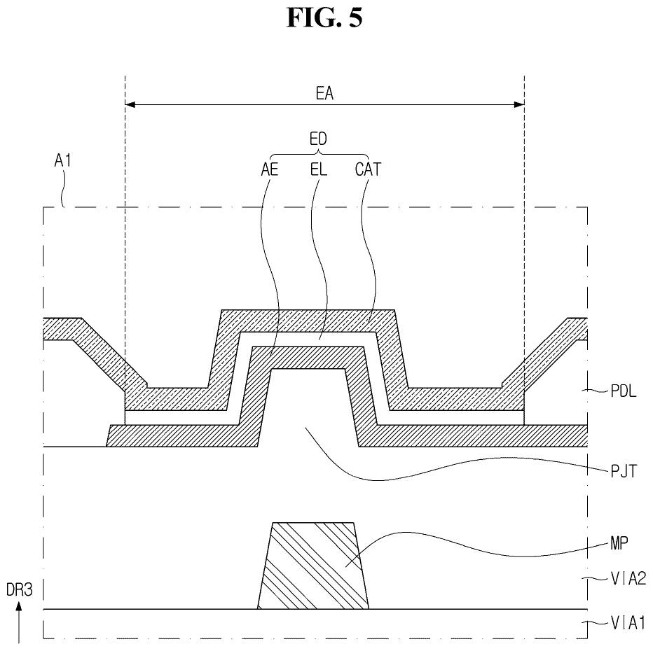

FIG. 4 is a cross-sectional view illustrating the display device according to an example embodiment, and FIG. 5 is an enlarged view of region A1 in FIG. 4.

As illustrated in FIGS. 4 and 5, the display panel 100 may include a first substrate SUB1, an intermediate layer ITL, a second substrate SUB2, a first light shielding layer MTL1, a buffer layer BUF, a first transistor T1, a first gate insulating layer GI1, a first capacitor C1, a second gate insulating layer GI2, a second light shielding layer MTL2, a first inter-layer insulating layer ILD1, a second transistor T2, a third gate insulating layer GI3, a second inter-layer insulating layer ILD2, first to fourth connection electrodes CE1, CE2, CE3, and CE4, a first via layer VIA1, the metal pattern MP, an anode connection electrode ANE, a second via layer VIA2, the pixel-defining layer PDL, the light emitting element ED, an encapsulation layer TFEL, a first insulating layer IL1, a bridge electrode BRE, a second insulating layer IL2, a touch electrode TE, and a planarization layer OC.

The first substrate SUB1 may be a base substrate, or a base member. The first substrate SUB1 may be a flexible substrate capable of being bent, folded, rolled and the like. For example, the first substrate SUB1 may include a polymer resin but is not limited thereto. As another example, the first substrate SUB1 may include a glass material or a metal material.

The intermediate layer ITL may be disposed on the first substrate SUB1. The intermediate layer ITL may be disposed between the first substrate SUB1 and the second substrate SUB2 and may include an inorganic insulating material.

The second substrate SUB2 may be disposed on the intermediate layer ITL. The second substrate SUB2 may include a material exemplified in the description of the first substrate SUB1.

The first light shielding layer MTL1 may be disposed on the second substrate SUB2. The first light shielding layer MTL1 may be disposed below a first semiconductor region (or first channel region) ACT1 of a first active layer of the first transistor T1 and may overlap the first semiconductor region ACT1. The first light shielding layer MTL1 may prevent or block light from passing through to the first semiconductor region ACT1 of the first transistor T1. The first light shielding layer MTL1 may include at least one among molybdenum (Mo), aluminum (Al), chrome (Cr), nickel (Ni), neodymium (Nd), and copper (Cu), but is not limited thereto.

The buffer layer BUF may be disposed on the first light shielding layer MTL1. For example, the buffer layer BUF may include an inorganic layer capable of preventing or suppressing permeation of air or moisture. For example, the buffer layer BUF may include a plurality of inorganic layers alternately stacked.

The first semiconductor region ACT1, a first source electrode (or region) SE1, and a first drain electrode (or region) DE1 of the first active layer of the first transistor T1 may be disposed on the buffer layer BUF. The first active layer (including the first semiconductor region ACT1) of the first transistor T1 may include a silicon-based material, and the first source electrode (or region) SE1 and the first drain electrode (or region) DE1 thereof may be formed by being doped with p-type impurities. For example, the first active layer (including the first semiconductor region ACTL1) may be formed of a low temperature poly-silicon (LTPS). The first source electrode SE1 of the first transistor T1 may be connected to a first connection electrode CE1. The first drain electrode DE1 of the first transistor T1 may be connected to a second connection electrode CE2.

The first gate insulating layer GI1 may be disposed on the first semiconductor region ACT1 of the first transistor T1. The first gate insulating layer GI1 may insulate the first semiconductor region ACT1 and the first gate electrode GE1 of the first transistor T1 from each other. The first gate insulating layer GI1 may include an inorganic insulating material.

The first gate electrode GE1 of the first transistor T1 and a first capacitor electrode CPE1 of the first capacitor C1 may be disposed on the first gate insulating layer GI1. The first gate electrode GE1 of the first transistor T1 may overlap the first semiconductor region (or first channel region) ACT1, and the first capacitor electrode CPE1 of the first capacitor C1 may overlap a second capacitor electrode CPE2.

The second gate insulating layer GI2 may be disposed on the first gate electrode GE1 of the first transistor T1 and the first capacitor electrode CPE1. The second gate insulating layer GI2 may insulate the first and second capacitor electrodes CPE1 and CPE2 from each other. The second gate insulating layer GI2 may include an inorganic insulating material.

The second capacitor electrode CPE2 of the first capacitor C1 and the second light shielding layer MTL2 may be disposed on the second gate insulating layer GI2. The second light shielding layer MTL2 may be disposed below a second semiconductor region (or second channel region) ACT2 of a second active layer of the second transistor T2 and may overlap the second semiconductor region ACT2. The second light shielding layer MTL2 may prevent or block light from passing through to the second semiconductor region ACT2 of the second transistor T2. The second light shielding layer MTL2 may include at least one among molybdenum (Mo), aluminum (Al), chrome (Cr), nickel (Ni), neodymium (Nd), and copper (Cu), but is not limited thereto.

The first inter-layer insulating layer ILD1 may be disposed on a second light shielding layer MTL2. The first inter-layer insulating layer ILD1 may insulate the second light shielding layer MTL2 and the second semiconductor region ACT2 of the second transistor T2 form each other. The first inter-layer insulating layer ILD1 may have a greater thickness than the first gate insulating layer GI1 or the second gate insulating layer GI2. The first inter-layer insulating layer ILD1 may include an inorganic insulating layer configured to prevent or suppress permeation of air or moisture. The first inter-layer insulating layer ILD1 may insulate the first transistor T1 including a silicon-based material and the second transistor T2 including an oxide-based material from each other.

The second active layer, including the second semiconductor region (or channel region) ACT2, a second drain electrode (or region) DE2, and a source electrode (or region) SE2, of the second transistor T2 may be disposed on the first inter-layer insulating layer ILD1. The second active layer including the second semiconductor region ACT2 of the second transistor T2 may include an oxide-based material, and the second drain electrode DE2 and the second source electrode SE2 of the second transistor T2 may be formed by being doped with n-type impurities. The second drain electrode DE2 of the second transistor T2 may be electrically connected to the second capacitor electrode CPE2 through a third connection electrode CE3. The second source electrode SE2 of the second transistor T2 may be connected to the fourth connection electrode CE4.

The third gate insulating layer GI3 may be disposed on the second active layer including the second semiconductor region ACT2 of the second transistor T2. The third gate insulating layer GI3 may insulate the second semiconductor region ACT2 and the second gate electrode GE2 of the second transistor T2 from each other.

The second gate electrode GE2 of the second transistor T2 may be disposed on the third gate insulating layer GI3. The second gate electrode GE2 of the second transistor T2 may overlap the second semiconductor region ACT2.

The second inter-layer insulating layer ILD2 may be disposed on the second gate electrode GE2 of the second transistor T2. The second inter-layer insulating layer ILD2 may insulate the first to fourth connection electrodes CE1, CE2, CE3, and CE4 and the second gate electrode GE2 of the second transistor T2 from each other. The second inter-layer insulating layer ILD2 may have a greater thickness than the third gate insulating layer GI3. The second inter-layer insulating layer ILD2 may include an inorganic insulating layer capable of preventing or suppressing permeation of air or moisture.

The first to fourth connection electrodes CE1, CE2, CE3, and CE4 may be disposed on the second inter-layer insulating layer ILD2. The first connection electrode CE1 may be connected to the first source electrode SE1 of the first transistor T1. The second connection electrode CE2 may be connected to the first drain electrode DE1 of the first transistor T1. The third connection electrode CE3 may electrically connect the second drain electrode DE2 of the second transistor T2 and the second capacitor electrode CPE2 to each other. The fourth connection electrode CE4 may be connected to the second source electrode SE2 of the second transistor T2.

The first via layer VIA1 may be disposed on the first to fourth connection electrodes CE1, CE2, CE3, and CE4. The first via layer VIA1 may insulate the first and second connection electrodes CE1 and CE2 and the metal pattern MP from each other. An upper surface of the first via layer VIA1 may be flat. The first via layer VIA1 may include an organic insulating material, such as polyimide PI.

The anode connection electrode ANE and the metal pattern MP may be disposed on the first via layer VIA1. The anode connection electrode ANE may electrically connect the third connection electrode CE3 and a pixel electrode (or anode) AE to each other. The metal pattern MP may overlap a projection PJT of the second via layer VIA2 in the third direction DR3 or a thickness direction. A planar and/or cross-sectional shape and a thickness of the metal pattern MP may be determined according to a planar and/or cross-sectional shape and a thickness of the projection PJT, respectively. A taper angle of the projections PJT may be determined according to the thickness of the metal pattern MP. For example, the greater the thickness of the metal pattern MP, the greater the taper angle of the projection PJT may be, and the smaller the thickness of the metal pattern MP, the smaller the taper angle of the projection PJT may be. One light emitting region EA may include a plurality of metal patterns MP and a plurality of projections PJT although FIG. 5 illustrates only one metal pattern MP and one projection PJT in a light emitting region EA. The metal pattern MP may be electrically floated but is not limited thereto.

The second via layer VIA2 may be disposed on the anode connection electrode ANE and the metal pattern MP. The second via layer VIA2 may insulate the metal pattern MP and the pixel electrode AE from each other. An upper surface of the second via layer VIA2 may be flat (except where the projection(s) PJT are). The second via layer VIA2 may include an organic insulating material, such as polyimide PI.

The second via layer VIA2 may include a projection PJT protruding in the third direction DR3 from a flat upper surface thereof. The projection PJT may be disposed in the light emitting region EA. The projection PJT may control a light emission angle(s) of the light emitting element ED. The light emission angle(s) of the light emitting element ED may be controlled according to the planar and/or cross-sectional shape, the taper angle, a quantity, and an arrangement of the projection(s) PJT. For example, the light emission angle(s) of the light emitting element ED may become more various or diverse where an edge of the projection PJT in a plan view has a curve than where that edge of the projection PJT in the plan view is a straight line. In addition, the greater the taper angle of the projection PJT, the more various or diverse the light emission angle(s) of the light emitting element ED may be. The projection PJT may be formed, for example, through an etch process using a half-tone mask, but the method for forming the projection PJT is not limited thereto. For example, the projection PJT may be formed by incorporating a metal pattern MP, as shown for example in FIGS. 4 and 5. As the display device 10 includes the metal pattern MP and the projection PJT, it is possible to control the light emission angle(s) of the light emitting element ED and to improve the viewing angle of the display device for the user.

The pixel-defining layer PDL may be disposed on the second via layer VIA2. The pixel-defining layer PDL may define the light emitting region EA or the opening region. The pixel-defining layer PDL may include an organic material, such as a material including a black pigment and the like, a benzocyclobutene resin, a polyimide resin, an acrylic resin, or photosensitive polymer, but the embodiments of the present disclosure are not limited thereto. Where the pixel-defining layer PDL is formed of a material including a black pigment, a black dye, or the like, the pixel-defining layer PDL may be a black bank. In this example, as the pixel-defining layer PDL includes a black pigment, a black dye, or the like, the pixel-defining layer PDL may block external light, thereby further improving luminance of the display device 10.

A spacer SPC may be disposed on the pixel-defining layer PDL. The spacer SPC may protrude from an upper surface of the pixel-defining layer PDL and support the encapsulation layer TFEL. The spacer SPC may include the same material as that of the pixel-defining layer PDL, but the embodiments of the present disclosure are not limited thereto.

The light emitting element ED may include the pixel electrode (or anode) AE, a light emitting layer EL, and a common electrode (or cathode) CAT. The pixel electrode AE may be disposed on the second via layer VIA2 and the projection PJT. The pixel electrode AE may overlap one among a plurality of light emitting regions EA defined by the pixel-defining layer PDL. The pixel electrode AE may fill or be disposed in an anode contact hole ACN penetrating the second via layer VIA2 to be in contact with the anode connection electrode ANE. The pixel electrode AE may receive a driving current from the pixel circuit of the pixel SP (for example, via the second transistor T2). The pixel electrode AE may be a first electrode (or anode) of the light emitting element ED.

The light emitting layer EL may be disposed on the pixel electrode AE. For example, the light emitting layer EL may be an organic light emitting layer formed of an organic material but is not limited thereto. Where the light emitting layer EL is an organic light emitting layer, the pixel circuit of the pixel SP may apply a certain voltage to the pixel electrode AE. When the common electrode CAT receives a common voltage, or a cathode voltage, a hole travels to the light emitting layer EL through a hole transport layer, and an electron travels to the light emitting layer EL through an electron transport layer, thereby the hole and the electron may be combined with each other on the light emitting layer EL to emit light.

The common electrode CAT may be disposed on the light emitting layer EL. For example, the common electrode CAT may be implemented in a form of an electrode common to some or all of the plurality of pixels SP without being divided for each of the plurality of pixels SP. The common electrode CAT may be a transparent electrode and may allow the light to pass therethrough. The common electrode CAT may be electrically connected to the low potential line VSL, and may receive the low potential voltage, the common voltage, or the cathode voltage. The common electrode CAT may be a second electrode (or cathode) of the light emitting element ED.

The encapsulation layer TFEL may be disposed on the light emitting element ED. The encapsulation layer TFEL may be disposed on the common electrode CAT and may cover the plurality of light emitting elements ED. The encapsulation layer TFEL may include a first encapsulation layer TFEL1, a second encapsulation layer TFEL2, and a third encapsulation layer TFEL3 sequentially stacked on the common electrode CAT.

The first encapsulation layer TFEL1 may be disposed on the common electrode CAT. The first encapsulation layer TFEL1 may include an inorganic material and may prevent or suppress permeation of oxygen or moisture to the light emitting element ED. For example, the first encapsulation layer TFEL1 may include at least one among a silicon nitride layer, a silicon oxynitride layer, a silicon oxide layer, a titanium oxide layer, an aluminum oxide layer, and an amorphous silicon layer, but is not limited thereto.

The second encapsulation layer TFEL2 may be disposed on the first encapsulation layer TFEL1 and may planarize an upper end of the plurality of the light emitting elements ED. The second encapsulation layer TFEL2 may include an organic material and may protect the light emitting element ED from foreign substances such as dust. For example, the second encapsulation layer TFEL2 may include an organic layer such as an acrylic resin, an epoxy resin, a phenolic resin, a polyamide resin, and a polyimide resin. The second encapsulation layer TFEL2 may be formed by hardening a monomer or applying a polymer.

The third encapsulation layer TFEL3 may be disposed on the second encapsulation layer TFEL2. The third encapsulation layer TFEL3 may include an inorganic material and may prevent or suppress permeation of oxygen or moisture to the light emitting element ED. For example, the third encapsulation layer TFEL3 may include a material exemplified in the description of the first encapsulation layer TFEL1.

The first insulating layer IL1 may be disposed on the encapsulation layer TFEL. The first insulating layer IL1 may be a layer having insulating and optical properties. The first insulating layer IL1 may include at least one inorganic layer.

A bridge electrode BRE may be disposed on the first insulating layer IL1. The bridge electrode BRE may be disposed on a different layer from the touch electrode TE and may electrically connect the touch electrodes TE spaced apart from each other.

The second insulating layer IL2 may be disposed on the bridge electrode BRE. The second insulating layer IL2 may insulate the bridge electrode BRE and the touch electrode TE from each other. The second insulating layer IL2 may include at least one inorganic layer.

The touch electrode TE may be disposed on the second insulating layer IL2. The touch electrode TE may be formed as a single layer of molybdenum (Mo), titanium (Ti), copper (Cu), aluminum (Al), or ITO (Indium Tin Oxide), or may be formed as a stacking structure of aluminum and titanium (Ti/Al/Ti), a stacking structure of aluminum and ITO (ITO/Al/ITO), a stacking structure of an APC alloy, and a stacking structure of an APC alloy and ITO (ITO/APC/ITO).

The planarization layer OC may be disposed on the touch electrode TE. The planarization layer OC may planarize an upper portion of the touch electrode TE and may protect the touch electrode TE. The planarization layer OC may include an organic insulating material.

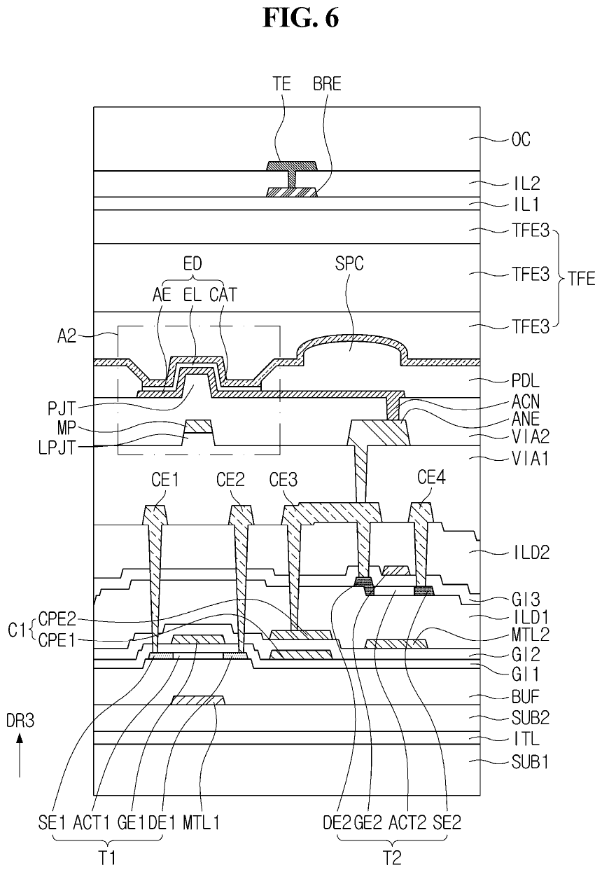

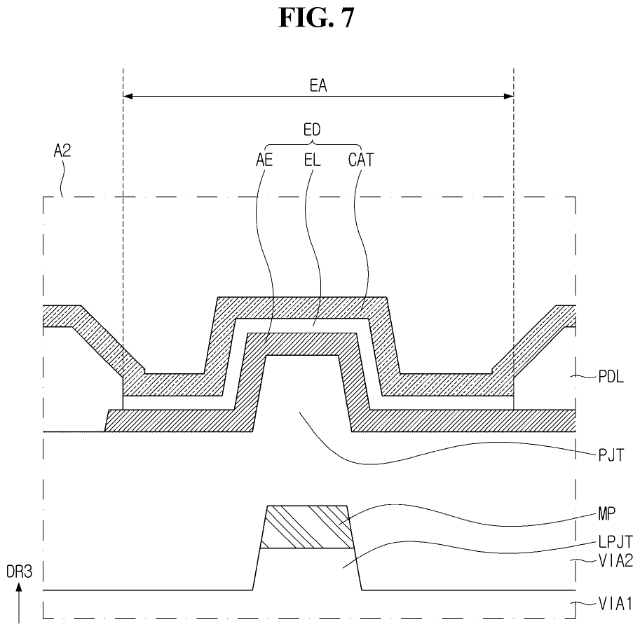

FIG. 6 is a cross-sectional view illustrating a display device according to another example embodiment, and FIG. 7 is an enlarged view of region A2 in FIG. 6. The example display device in FIGS. 6 and 7 further includes a lower projection LPJT to the example display device illustrated in FIGS. 4 and 5, and components which are the same as the above-described components will be briefly described or omitted.

As shown in FIGS. 6 and 7, the display panel 100 may include the first substrate SUB1, the intermediate layer ITL, the second substrate SUB2, the first light shielding layer MTL1, the buffer layer BUF, the first transistor T1, the first gate insulating layer GI1, the first capacitor C1, the second gate insulating layer GI2, the second light shielding layer MTL2, the first inter-layer insulating layer ILD1, the second transistor T2, the third gate insulating layer GI3, the second inter-layer insulating layer ILD2, the first to fourth connection electrodes CE1, CE2, CE3, and CE4, the first via layer VIA1, the metal pattern MP, the anode connection electrode ANE, the second via layer VIA2, the pixel-defining layer PDL, the light emitting element ED, the encapsulation layer TFEL, the first insulating layer IL1, the bridge electrode BRE, the second insulating layer IL2, the touch electrode TE, and the planarization layer OC.

The first via layer VIA1 may be disposed on the first to fourth connection electrodes CE1, CE2, CE3, and CE4. The first via layer VIA1 may include a lower projection LPJT protruding in the third direction DR3 from a flat upper surface thereof. The lower projection LPJT may support the metal pattern MP. The lower projection LPJT may overlap the projection of the second via layer VIA2 in the third direction DR3, or the thickness direction. A planar and/or cross-sectional shape of the low projection LPJT may determine a planar and/or cross-sectional shape of the metal pattern MP, respectively. A taper angle and a thickness of the projection PJT may be determined according to a sum of thicknesses of the lower projection LPJT and the metal pattern MP. For example, the greater the the sum of thicknesses of the lower projection LPJT and the metal pattern MP, the greater the taper angle of the projection PJT may be, and the smaller the sum of thicknesses of the lower projection LPJT and the metal pattern MP, the smaller the taper angle of the projection PJT may be. One light emitting region EA may include a plurality of lower projections LPJT, a plurality of metal patterns MP, and a plurality of projections PJT. The lower projection LPJT may be formed through an etch process using a half-tone mask, but the method for forming the lower projection LPJT is not limited thereto.

The anode connection electrode ANE may be disposed on the first via layer VIA1, and the metal pattern MP may be disposed on the lower projection LPJT of the first via layer VIA1. The metal pattern MP may overlap the projection PJT of the second via layer VIA2 in the third direction DR3 or the thickness direction. A planar and/or cross-sectional shape of the metal pattern MP may determine a planar and/or cross-sectional shape of the projection PJT. The metal pattern MP may be electrically floated but is not limited thereto.

The second via layer VIA2 may be disposed on the anode connection electrode ANE and the metal pattern MP. The second via layer VIA2 may include the projection PJT protruding in the third direction DR3 from a flat upper surface thereof. The projection PJT may be disposed in the light emitting region EA. The projection PJT may control the light emission angle(s) of the light emitting element ED. The light emission angle(s) of the light emitting element ED may be controlled according to the planar and/or cross-sectional shape, the taper angle, the quantity, and the arrangement of the projection PJT. For example, the light emission angle(s) of the light emitting element ED may become more various or diverse where an edge of the projection PJT in a plan view has a curve than where that edge of the projection PJT in the plan view is a straight line. In addition, the greater the taper angle of the projection PJT, the more various or diverse the light emission angle(s) of the light emitting element ED may be. The projection PJT may be formed through an etch process using a half-tone mask, but the method for forming the projection PJT is not limited thereto. For example, the projection PJT may be formed by incorporating a lower projection LPJT and/or a metal pattern MP, as shown for example in FIGS. 6 and 7. As the display device 10 includes the lower projection LPJT, the metal pattern MP, and the projection PJT, it is possible to control the light emission angle(s) of the light emitting element ED and to improve the viewing angle of the display device for the user.

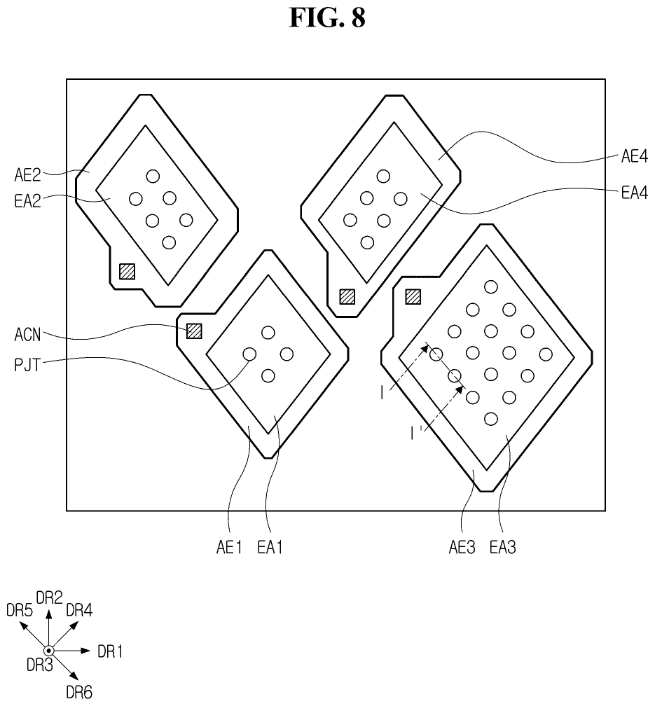

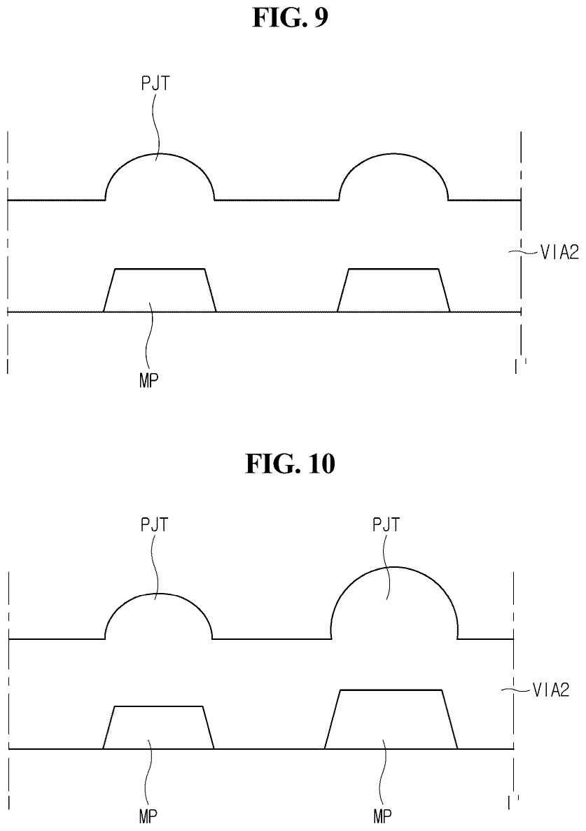

FIG. 8 is an example of a plan view illustrating a plurality of pixels in the display device according to an example embodiment, FIG. 9 is an example of a cross-sectional view taken along line I-I′ in FIG. 8, and FIG. 10 is another example of a cross-sectional view taken along line I-I′ in FIG. 8.

As illustrated in FIGS. 8 to 10, the display region DA may include first to fourth light emitting regions EA1, EA2, EA3, and EA4. The first to fourth light emitting regions EA1, EA2, EA3, and EA4 may be defined by the pixel-defining layer PDL (see, e.g., FIGS. 4-7). Each of the first to fourth light emitting regions EA1, EA2, EA3, and EA4 may emit light from the corresponding light emitting element ED. For example, the first light emitting region EA1 may emit light in a first color, or red light, the second and fourth light emitting regions EA2 and EA4 may emit light in a second color, or green light, and the third light emitting region EA3 may emit light in a third color, or blue light, but are not limited thereto. One unit pixel may include the first to fourth light emitting regions EA1, EA2, EA3, and EA4, and may express a white grayscale, but the configuration of the unit pixel is not limited thereto.

An area (or a planar area) of each of the first to fourth light emitting regions EA1, EA2, EA3, and EA4 may be different from each other. For example, an area of the third light emitting region EA3 may be greater than that of the first light emitting region EA1, and an area of the first light emitting region EA1 may be greater than that of the second or fourth light emitting region EA2 and EA4, but the relative configuration of the light emitting regions is not limited thereto. As another example, an area of each of the first to fourth light emitting regions EA1, EA2, EA3, and EA4 may be the same.

Each of the first to fourth pixel electrodes AE1, AE2, AE3, and AE4 may overlap each of the first to fourth light emitting regions EA1, EA2, EA3, and EA4. In an example manufacturing process of the display device 10, each of the first to fourth pixel electrodes AE1, AE2, AE3, and AE4 may be exposed through each of the first to fourth light emitting regions EA1, EA2, EA3, and EA4. Each of the first to fourth pixel electrodes AE1, AE2, AE3, and AE4 may be in contact with the anode connection electrode ANE through the anode contact hole can, as shown for example in FIG. 4 or 6.

Each of the first to fourth light emitting regions EA1, EA2, EA3, and EA4 may include the plurality of projections PJT. The plurality of projections PJT may be disposed in a matrix arrangement, but the arrangement of the projection PJT is not limited to what is illustrated in FIG. 8. The arrangement of the projections PJT may be changed according to a size, a shape, and a color characteristic of the corresponding light emitting region EA.

For example, the first light emitting region EA1 may include the plurality of projections PJT disposed in a two-by-two arrangement. Each of the second and fourth light emitting regions EA2 and EA4 may include the plurality of projections PJT disposed in a two-by-three arrangement, or a three-by-two arrangement. The third light emitting region EA3 may include plurality of projections PJT disposed in a four-by-four arrangement.

In FIG. 9, the plurality of metal patterns may be in one-to-one correspondence with the plurality of projections PJT. The plurality of metal patterns MP may have the same shape and size. A planar and/or cross-sectional shape and a thickness of the plurality of metal patterns MP may be substantially the same. Therefore, the taper angle and the thickness of the plurality of projections PJT in correspondence with the plurality of metal patterns MP may be substantially the same.

In FIG. 10, the plurality of metal patterns MP may be in one-to-one correspondence with the plurality of projections PJT, but the plurality of metal patterns MP may have different shapes and/or sizes from each other. Thicknesses of the plurality of metal patterns MP may be different from each other. The thickness of the metal patterns MP may determine a thickness of the projection PJT. The taper angle of the projection PJT may be determined according to the taper angle and/or the thickness of the metal pattern MP. For example, the greater the thickness of the metal patterns MP, the greater the taper angle and the thickness of the projection PJT may be, and the smaller the thickness of the metal pattern MP, the smaller the taper angle and the thickness of the projection PJT may be.

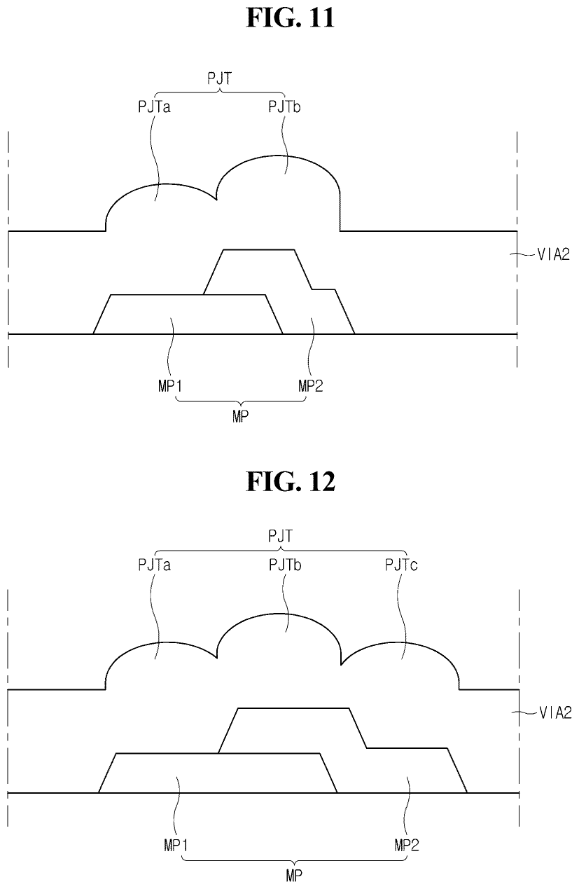

FIG. 11 is a cross-sectional view illustrating another example of the metal pattern(s) and the projection(s) in the display device according to an example embodiment.

As shown in FIG. 11, the first metal pattern MP1 may be disposed on the first via layer VIA1, and the second metal pattern MP2 may be disposed on the first metal pattern MP1 and the first via layer VIA1. Part of the second metal pattern MP2 may overlap the first metal pattern MP1, and another part of the second metal pattern MP2 may not overlap the first metal pattern MP1.

The second via layer VIA2 may include the projection PJT protruding in the third direction DR3 from a flat upper surface thereof. The projection PJT may include a first portion PJTa and a second portion PJTb. The first portion PJTa of the projection PJT may overlap the first metal pattern MP1, and the second portion PJTb of the projection PJT may overlap the second metal pattern MP2. A planar and/or cross-sectional shape and a thickness of the first portion PJTa of the projection PJT may be determined according to a planar and/or cross-sectional shape and a thickness of the first metal pattern MP1. A planar and/or cross-sectional shape and a thickness of the second portion PJTb of the projection PJT may be determined according to a planar and/or cross-sectional shape of the second metal pattern MP2 and a sum of the thicknesses of the first and second metal patterns MP1 and MP2. A taper angle of the second portion PJTb of the projection PJT may be greater than a taper angle of the first portion PJTa of the projection PJT. As the projection PJT includes the first and second portions PJTa and PJTb having different thicknesses and taper angles from each other, it is possible to control the light emission angle(s) of the light emitting element(s) ED more variously or diversely, and to improve the viewing angle of the display device for the user.

FIG. 12 is a cross-sectional view illustrating another example of the metal pattern and the projection in the display device according to an example embodiment.

As illustrated in FIG. 12, the first metal pattern MP1 may be disposed on the first via layer VIA1, and the second metal pattern MP2 may be disposed on the first metal pattern MP1 and the first via layer VIA1. A part of the second metal pattern MP2 may overlap the first metal pattern MP1, and another part of the second metal pattern MP2 may not overlap the first metal pattern MP1.

The projection PJT may include a first portion PJTa, a second portion PJTb, and a third portion PJTc. The first portion PJTa of the projection PJT may overlap the first metal pattern MP1, the second portion PJTb of the projection PJT may overlap the first and second metal patterns MP1 and MP2, and the third portion PJTc of the projection PJT may overlap the second metal pattern MP2. A planar and/or cross-sectional shape and a thickness of the first portion PJTa of the projection PJT may be determined according to a planar and/or cross-sectional shape and a thickness of the first metal pattern MP1. A planar and/or cross-sectional shape and a thickness of the second portion PJTb of the projection PJT may be determined according to a planar and/or cross-sectional shape of the first and second metal patterns MP1 and MP2, and a sum of the thicknesses of the first and second metal patterns MP1 and MP2. A planar and/or cross-sectional shape and a thickness of the third portion PJTc of the projection PJT may be determined according to a planar shape and a thickness of the second metal pattern MP2, e.g., the portion of the second metal pattern MP2, not overlapping the first metal pattern MP1.

A taper angle of the second portion PJTb of the projection PJT may be greater than a taper angle of the first portion PJTa or the third portion PJTc. As the projection PJT includes the first to third portions PJTa, PJTb, and PJTc having different thicknesses and taper angles from one another, it is possible to control the light emission angle(s) of the light emitting element(s) ED more diversely or variously, and to improve the viewing angle of the display device for the user.

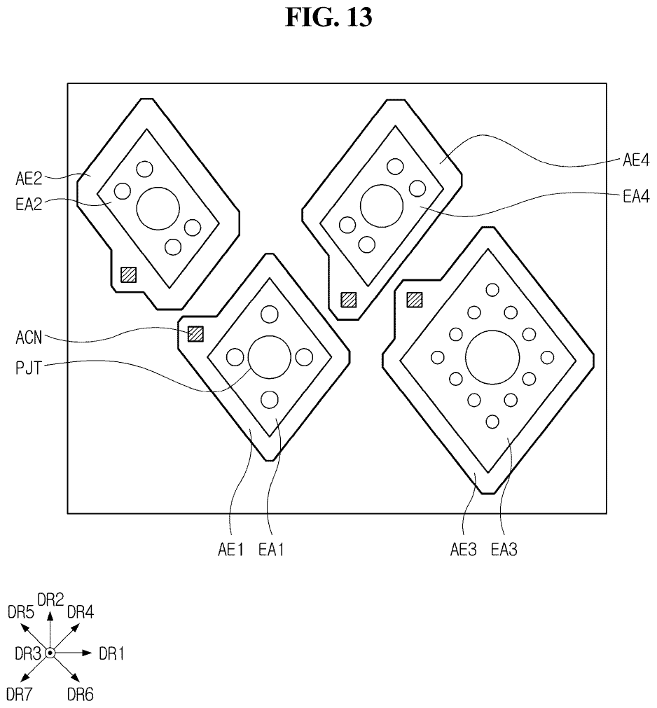

FIG. 13 is another example of a plan view illustrating a plurality of pixels in the display device according to another example embodiment. The example display device in FIG. 13 is different from the example display device in FIG. 8 in that the display device in FIG. 13 has a different configuration of the first and second projections PJT1 and PJT2. The components in FIG. 13 which are the same as the above-described components (e.g., in connection with the example display device of FIG. 8) will be briefly described or omitted.

As illustrated in FIG. 13, the display region DA may include first to fourth light emitting regions EA1, EA2, EA3, and EA4. Each of the first to fourth pixel electrodes AE1, AE2, AE3, and AE4 may overlap a corresponding one of the first to fourth light emitting regions EA1, EA2, EA3, and EA4. Each of the first to fourth pixel electrodes AE1, AE2, AE3, and AE4 may be in contact with the corresponding anode connection electrode ANE through the corresponding anode contact hole, as shown for example in FIG. 4 or 6.

Each of the first to fourth light emitting regions EA1, EA2, EA3, and EA4 may include the first projection(s) PJT1 and the second projection(s) PJT2. A size of the first projection PJT1 may be greater than a size of the second projection PJT2. The first projection PJT1 may be disposed at a center of each of the first to fourth light emitting regions EA1, EA2, EA3, and EA4, and a plurality of second projections PJT2 may surround the first projection PJT1. The arrangement of the first and second projections PJT1 and PJT2 is not limited to what is illustrated in FIG. 13. The arrangement of the first and second projections PJT1 and PJT2 may be changed according to a size, a shape, and a color characteristic of the light emitting region EA.

The first to fourth light emitting regions EA1, EA2, EA3, and EA4 may have different arrangements of the first and second projections PJT1 and PJT2 from one another, according to a planar shape and a size of each of the first to fourth light emitting regions EA1, EA2, EA3, and EA4. For example, the first light emitting region EA1 may include the first projection PJT1 and four second projections PJT2. The second projections PJT2 may be disposed in the first direction DR1 of the first projection PJT1, an opposite direction to the first direction DR1, the second direction DR2, and an opposite direction to the second direction DR2, respectively, from the first projection PJT1.

The second light emitting region EA2 may include the first projection PJT1 and four second projections PJT2. The second projections PJT2 may be disposed in a fifth direction DR5 and a sixth direction DR6 from the first projection PJT1, respectively.

The third light emitting region EA3 may include the first projection PJT1 and twelve second projections PJT2. The second projections PJT2 may be disposed along four sides of the third light emitting regions EA3 (for example, surrounding the first projection PJT1).

The fourth light emitting region EA4 may include the first projection PJT1 and four second projections PJT2. The second projections PJT2 may be disposed in a fourth direction DR4 and a seventh direction DR7 from the first projection PJT1, respectively.

As each of the first to fourth light emitting regions EA1, EA2, EA3 and EA4 includes the first and second projections PJT1 and PJT2 having different sizes from each other, it is possible to control the light emission angle(s) of the light emitting element(s) ED more diversely or variously, and to improve the viewing angle of the display device for the user.

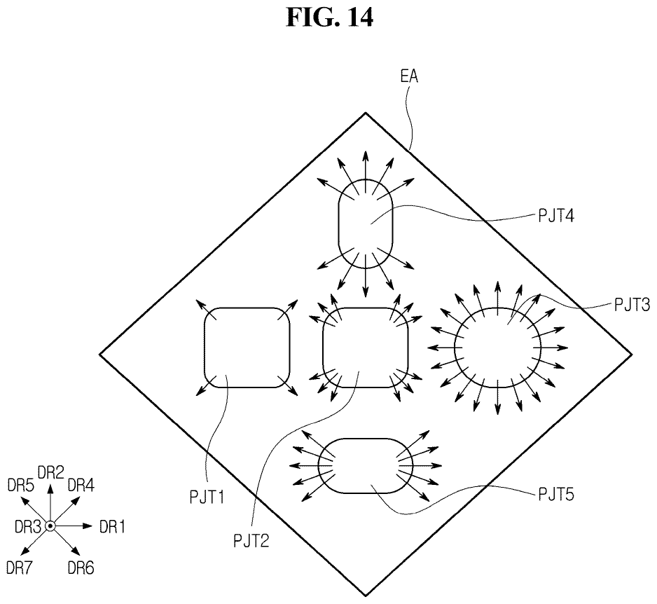

FIG. 14 is a plan view illustrating various examples of the projection in the display device according to example embodiments.

As illustrated in FIG. 14, the light emitting region EA may include one or more of first to fifth projections PJT1, PJT2, PJT3, PJT4, and PJT5.

The first projection PJT1 may include a round portion (or corner) disposed in each of the fourth to seventh directions DR4, DR5, DR6, and DR7 from the center of the first projection PJT1 (in a plan view). Here, a round portion may correspond to a curved corner disposed between adjacent linear sides. A size (e.g., a planar size) of the round portion(s) of the first projection PJT1 may be smaller than a size (e.g., a planar size) of the round portion(s) of the second projection PJT2. As the first projection PJT1 includes the round portions, it is possible to control the light emission angle(s) of the light emitting element ED.

The second projection PJT2 may include a round portion (or corner) disposed in each of the fourth to seventh directions DR4, DR5, DR6, and DR7 from the center of the second projection PJT2 (in a plan view). A size (e.g., a planar size)of the round portion(s) of the second projection PJT2 may be smaller than a size (e.g., a planar size)of the round portion(s) of the first projection PJT1. Therefore, the round portion(s) of the second projection PJT2 may emit light of the light emitting element ED at more various or diverse angles than do the round portion(s) of the first projection PJT1.

The third projection PJT3 may have a circular shape or an oval shape (in a plan view). Therefore, the third projection PJT3 may emit light of the light emitting element ED in all directions.

The fourth projection PJT4 may include a round portion disposed in the second direction DR2 and an opposite direction to the second direction DR2 from the center portion of the fourth projection PJT4. The fourth projection PJT4 may include a round portion disposed at an upper side and a lower side. Therefore, the fourth projection PJT4 may emit light of the light emitting element ED toward the upper side and the lower side at more various or diverse angles.

The fifth projection PJT5 may include a round portion disposed in the first direction DR1 and an opposite direction to the first direction DR1 from the center portion of the fifth projection PJT5. The fifth projection PJT5 may include a round portion disposed at a left side and a right side. Therefore, the fifth projection PJT5 may emit light of the light emitting element ED toward the left side and the right side at more various or diverse angles. Therefore, as the display device 10 includes the projections PJT having various shapes and/or sizes, the display device 10 may control the light emission angle(s) of the light emitting element(s) ED more diversely or variously, and may improve the viewing angle of the display device for the user.

The display device 10 according to various example embodiments of the present disclosure may be described as below.

A display device according to one or more embodiments of the present disclosure may include: a substrate including a first pixel having a first light emitting region; at least one transistor on the substrate; a first via layer on the at least one transistor; at least one metal pattern on the first via layer; a second via layer on the at least one metal pattern and comprising at least one projection overlapping the at least one metal pattern, the at least one projection being in the first light emitting region; a pixel-defining layer on the second via layer and configured to define the first light emitting region; and a pixel electrode on the second via layer and the at least one projection.

The display device according to various embodiments of the present disclosure may further include: a connection electrode on the at least one transistor; and an anode connection electrode on a same underlying layer as the at least one metal pattern and configured to electrically connect the connection electrode and the pixel electrode via a contact hole through the first via layer. The pixel electrode may be electrically connected to the anode connection electrode via a contact hole through the second via layer.

In the display device according to various embodiments of the present disclosure, the at least one transistor may include a first transistor on the substrate and a second transistor above the first transistor, the second transistor comprising a different semiconductor material from a semiconductor material of the first transistor, and the connection electrode may be configured to electrically connect the second transistor and the anode connection electrode.

In the display device according to various embodiments of the present disclosure, a planar shape and a thickness of the at least one projection may correspond to a planar shape and a thickness of the at least one metal pattern.

In the display device according to various embodiments of the present disclosure, the at least one projection may comprise a plurality of projections disposed in the first light emitting region, and the at least one metal pattern may comprise a plurality of metal patterns in one-to-one correspondence with the plurality of projections.

In the display device according to various embodiments of the present disclosure, the substrate may further include a second pixel having a second light emitting region and a third pixel having a third light emitting region. The first light emitting region may be configured to emit light of a first color, the second light emitting region may be configured to emit light of a second color different from the first color, and the third light emitting region may be configured to emit light of a third color different from the first color and the second color. The third light emitting region may include a greater number of projections than the first light emitting region or the second light emitting region does.

In the display device according to various embodiments of the present disclosure, the plurality of projections have a same taper angle or a same thickness.

In the display device according to various embodiments of the present disclosure, the plurality of metal patterns may have different shapes or different thicknesses from each other, and the plurality of projections may have different taper angles or different thicknesses from each other in correspondence with the different shapes or the different thicknesses of the plurality of metal patterns.

In the display device according to various embodiments of the present disclosure, the plurality of projections may comprise a first projection disposed at a center of the first light emitting region and a plurality of second projections surrounding the first projection in a plan view.

In the display device according to various embodiments of the present disclosure, the at least one metal pattern comprises a first metal pattern disposed on the first via layer and a second metal pattern disposed on the first metal pattern and the first via layer, and the at least one projection may comprise a first portion overlapping the first metal pattern and a second portion overlapping the second metal pattern.

In the display device according to various embodiments of the present disclosure, a thickness of the first portion of the at least one projection may correspond to a thickness of the first metal pattern, and a thickness of the second portion of the at least one projection may correspond to a sum of the thickness of the first metal pattern and a thickness of the second metal pattern.

In the display device according to various embodiments of the present disclosure, the at least one metal pattern may comprise a first metal pattern disposed on the first via layer and a second metal pattern disposed on the first metal pattern and the first via layer. The at least one projection may comprise a first portion overlapping the first metal pattern, a second portion overlapping the first metal pattern and the second metal pattern, and a third portion overlapping the second metal pattern.

In the display device according to various embodiments of the present disclosure, a thickness of the first portion of the at least one projection may correspond to a thickness of the first metal pattern, a thickness of the second portion of the at least one projection may correspond to a sum of the thickness of the first metal pattern and a thickness of a portion of the second metal pattern on the first metal pattern, and a thickness of the third portion of the at least one projection may correspond to a thickness of another portion of the second metal pattern not on the first metal pattern.

In the display device according to various embodiments of the present disclosure, the first via layer may comprise at least one lower projection protruding from an upper surface of the first via layer in a direction away from the substrate, and the at least one metal pattern may be disposed on the at least one lower projection. The at least one projection may protrude from an upper surface of the second via layer in the direction away from the substrate and may overlap the at least one lower projection in the first light emitting region

In the display device according to various embodiments of the present disclosure, a taper angle or a thickness of the at least one projection is determined according to a sum of thicknesses of the at least one lower projection and the at least one metal pattern.

In another aspect, a display device according to one or more embodiments of the present disclosure may include: a plurality of pixels defined on a substrate, including a first pixel having a first light emitting region; a transistor on the substrate; a first via layer on the transistor; at least one metal pattern on the first via layer; a second via layer on the at least one metal pattern and comprising at least one projection overlapping the at least one metal pattern in the first light emitting region, the at least one projection protruding from an upper surface of the second via layer in a direction away from the substrate; a pixel-defining layer on the second via layer and including an opening to define the first light emitting region; and a light emitting element on the second via layer and overlapping the at least one projection and the at least one metal pattern in the first light emitting region.

In the display device according to various embodiments of the present disclosure, the light emitting element may includes a pixel electrode on the second via layer and overlapping the at least one projection and the at least one metal pattern in the first light emitting region, a light emission layer on the pixel electrode and configured to emit light, and a common electrode on the light emission layer. At least one of the pixel electrode, the light emission layer, and the common electrode may include a shape corresponding to a shape of the at least one projection in the first light emitting region.

The display device according to various embodiments of the present disclosure may further include: a connection electrode on the transistor; and an anode connection electrode on a same underlying layer as the at least one metal pattern and electrically connecting the connection electrode with the light emitting element via a contact hole through the first via layer. The light emitting element may be electrically connected to the anode connection electrode via a contact hole through the second via layer.

In the display device according to various embodiments of the present disclosure, the at least one metal pattern may comprise a plurality of metal patterns on the first via layer in the first light emitting region, and the at least one projection includes a plurality of projections respectively overlapping the plurality of metal patterns in the first light emitting region.

In the display device according to various embodiments of the present disclosure, the at least one projection includes one or more curved edges in a plan view.

Various example embodiments of the present disclosure have been described with reference to accompanying drawings. Those of ordinary skill in the art will recognize that the present disclosure may be embodied in other specific forms without departing from its spirit or essential characteristics. The example embodiments described above are to be considered in all respects only as illustrative and not restrictive. The protected scope of the present disclosure may therefore be indicated by the appended claims and their equivalents rather than by the foregoing description. All changes which come within meaning and range of equivalency of the claims are to be encompassed within the scope of the present disclosure.

What is claimed is:

1. A display device, comprising:
a substrate including a first pixel having a first light emitting region;
at least one transistor on the substrate;
a first via layer on the at least one transistor;
at least one metal pattern on the first via layer;
a second via layer on the at least one metal pattern and comprising at least one projection overlapping the at least one metal pattern, the at least one projection being in the first light emitting region;
a pixel-defining layer on the second via layer and configured to define the first light emitting region; and
a pixel electrode on the second via layer and the at least one projection.

2. The display device of claim 1, further comprising:
a connection electrode on the at least one transistor; and
an anode connection electrode on a same underlying layer as the at least one metal pattern and configured to electrically connect the connection electrode and the pixel electrode via a contact hole through the first via layer,
wherein the pixel electrode is electrically connected to the anode connection electrode via a contact hole through the second via layer.

3. The display device of claim 2, wherein:
the at least one transistor includes a first transistor on the substrate and a second transistor above the first transistor, the second transistor comprising a different semiconductor material from a semiconductor material of the first transistor; and
the connection electrode is configured to electrically connect the second transistor and the anode connection electrode.

4. The display device of claim 1, wherein a planar shape and a thickness of the at least one projection correspond to a planar shape and a thickness of the at least one metal pattern.

5. The display device of claim 1, wherein:
the at least one projection comprises a plurality of projections disposed in the first light emitting region; and
the at least one metal pattern comprises a plurality of metal patterns in one-to-one correspondence with the plurality of projections.

6. The display device of claim 5, wherein:
the substrate further includes a second pixel having a second light emitting region and a third pixel having a third light emitting region;
the first light emitting region is configured to emit light of a first color, the second light emitting region is configured to emit light of a second color different from the first color, and the third light emitting region is configured to emit light of a third color different from the first color and the second color; and
the third light emitting region includes a greater number of projections than the first light emitting region or the second light emitting region does.

7. The display device of claim 5, wherein the plurality of projections have a same taper angle or a same thickness.

8. The display device of claim 5, wherein the plurality of metal patterns have different shapes or different thicknesses from each other, and the plurality of projections have different taper angles or different thicknesses from each other in correspondence with the different shapes or the different thicknesses of the plurality of metal patterns.

9. The display device of claim 5, wherein the plurality of projections comprise a first projection disposed at a center of the first light emitting region and a plurality of second projections surrounding the first projection in a plan view.

10. The display device of claim 1, wherein:
the at least one metal pattern comprises a first metal pattern disposed on the first via layer and a second metal pattern disposed on the first metal pattern and the first via layer; and
the at least one projection comprises a first portion overlapping the first metal pattern and a second portion overlapping the second metal pattern.

11. The display device of claim 10, wherein:
a thickness of the first portion of the at least one projection corresponds to a thickness of the first metal pattern; and
a thickness of the second portion of the at least one projection corresponds to a sum of the thickness of the first metal pattern and a thickness of the second metal pattern.

12. The display device of claim 1, wherein:
the at least one metal pattern comprises a first metal pattern disposed on the first via layer and a second metal pattern disposed on the first metal pattern and the first via layer; and
the at least one projection comprises a first portion overlapping the first metal pattern, a second portion overlapping the first metal pattern and the second metal pattern, and a third portion overlapping the second metal pattern.

13. The display device of claim 12, wherein:
a thickness of the first portion of the at least one projection corresponds to a thickness of the first metal pattern;
a thickness of the second portion of the at least one projection corresponds to a sum of the thickness of the first metal pattern and a thickness of a portion of the second metal pattern on the first metal pattern; and
a thickness of the third portion of the at least one projection corresponds to a thickness of another portion of the second metal pattern not on the first metal pattern.

14. The display device of claim 1, wherein:
the first via layer comprises at least one lower projection protruding from an upper surface of the first via layer in a direction away from the substrate;
the at least one metal pattern is disposed on the at least one lower projection; and
the at least one projection protrudes from an upper surface of the second via layer in the direction away from the substrate and overlaps the at least one lower projection in the first light emitting region.

15. The display device of claim 14, wherein a taper angle or a thickness of the at least one projection is determined according to a sum of thicknesses of the at least one lower projection and the at least one metal pattern.

16. A display device, comprising:
a plurality of pixels defined on a substrate, including a first pixel having a first light emitting region;
a transistor on the substrate;
a first via layer on the transistor;
at least one metal pattern on the first via layer;
a second via layer on the at least one metal pattern and comprising at least one projection overlapping the at least one metal pattern in the first light emitting region, the at least one projection protruding from an upper surface of the second via layer in a direction away from the substrate;
a pixel-defining layer on the second via layer and including an opening to define the first light emitting region; and
a light emitting element on the second via layer and overlapping the at least one projection and the at least one metal pattern in the first light emitting region.

17. The display device of claim 16, wherein:
the light emitting element includes:
a pixel electrode on the second via layer and overlapping the at least one projection and the at least one metal pattern in the first light emitting region;
a light emission layer on the pixel electrode and configured to emit light; and
a common electrode on the light emission layer; and
at least one of the pixel electrode, the light emission layer, and the common electrode includes a shape corresponding to a shape of the at least one projection in the first light emitting region.

18. The display device of claim 16, further comprising:
a connection electrode on the transistor; and
an anode connection electrode on a same underlying layer as the at least one metal pattern and electrically connecting the connection electrode with the light emitting element via a contact hole through the first via layer,
wherein the light emitting element is electrically connected to the anode connection electrode via a contact hole through the second via layer.

19. The display device of claim 16, wherein:
the at least one metal pattern comprises a plurality of metal patterns on the first via layer in the first light emitting region; and
the at least one projection includes a plurality of projections respectively overlapping the plurality of metal patterns in the first light emitting region.

20. The display device of claim 16, wherein the at least one projection includes one or more curved edges in a plan view.
